(19) United States
(12) Patent Application Publication
(10) Pub. No.: US 2024/0170919 A1
(43) Pub. Date: May 23, 2024

(54) DEVICE COUPON

(71) Applicant: ROCKLEY PHOTONICS LIMITED, Altrincham, Chesire (GB)

(72) Inventors: Guomin Yu, Glendora, CA (US); Aaron John Zilkie, Pasadena, CA (US)

(21) Appl. No.: 18/281,760

(22) PCT Filed: Mar. 16, 2022
(86) PCT No.: PCT/EP2022/056889

§ 371 Date: Sep. 12, 2023

(30) Foreign Application Priority Data
Mar. 18, 2021 (GB) 2103799.9

(51) Int. Cl. H01S 5/12; H01S 5/0234; H01S 5/028; H01S 5/10; H01S 5/22; H01S 5/343

(52) U.S. Cl. CPC H01S 5/1203; H01S 5/0287; H01S 5/1082; H01S 5/22; H01S 5/34313; H01S 5/0234; H01S 5/2214

(57) ABSTRACT

A method of preparing a distributed feedback laser. The distributed feedback laser comprises an active waveguide with a reflective facet. The method comprises: etching a grating into the distributed feedback laser; and etching an output facet into the active waveguide.

### FIELD OF THE INVENTION

The present invention relates to a device coupon, a method of preparing a device coupon, an optoelectronic device, and a method of fabricating an optoelectronic device.

### BACKGROUND

Hybrid integration of III-V semiconductor based electro-optical devices (e.g. lasers, or modulators), with silicon-on-insulator (SOI) platforms confers the advantage of combining the best parts of both material systems.

However, conventional chip bonding processes typically use flip-chip bonding, in which the III-V semiconductor based device is inverted and bonded into a cavity on the SOI platform. This manufacturing process can be costly and have a low yield, because of the metal bumping requirements for the die bonding and difficulties in accurately controlling the alignment of the respective components.

Micro-transfer printing (MTP) is therefore being investigated as an alternative way to integrate III-V semiconductor based devices within SOI wafer. In these methods, the III-V semiconductor based device can be printed into a cavity on the SOI in the same orientation in which it was manufactured and without the need for metal bumping. The alignment between the III-V semiconductor based waveguide and the SOI waveguide is thereby predetermined in the vertical direction (z direction). The requirements for alignment are therefore reduced from three dimension to two, which can be more easily facilitated.

Specifically, it is of interest to utilise MTP processing to produce Distributed feedback (DFB) lasers. DFB lasers are a type of laser where the active region of the device contains a periodically structured element or grating. In conventional DFB lasers, the grating extends over an output or DFB laser facet of the laser due to the limited accuracy with which the laser facet can be cleaved (typically ±a few microns). Because of this uncertainty in cleaving the output facet, the grating phase over the DFB laser facet is also uncertain. This adversely affects the DFB laser side mode suppress ratio (SMSR) and lowers the yield of the DFB laser.

### SUMMARY

Accordingly, in a first aspect, embodiments of the invention provide a method of preparing a distributed feedback laser, the distributed feedback laser comprising an active waveguide and a reflective facet;
the method comprising:
   etching a grating into the distributed feedback laser; and
   etching an output facet into the active waveguide such that the grating is located between the reflective facet and the output facet.

Such a distributed feedback laser prepared using the method above does not suffer the deficiencies identified above. Specifically, as the output facet is etched there is little or no phase change from the grating near the facet as it can be located more accurately than conventionally possible (for example to within an accuracy of ±100 nm). Accordingly, the SMSR is not affected in the same manner as in the prior art and the DFB laser has an improved yield.

Optional features of the invention will now be set out. These are applicable singly or in any combination with any aspect of the invention.

The reflective facet may be an etched facet. The reflective facet may be etched at the same time, or before, or after, the output facet is etched. The reflective facet may be a cleaved facet. The grating may be etched before the output facet and/or reflective facet.

The grating may be spaced from the output facet and may extend part way along the active waveguide. The grating may be spaced from the output facet by a distance of at least 0.5 μm and no more than 50 μm. The grating may be spaced from the output facet by a distance of at least 0.5 μm, and in some examples at least 5 μm. That is, there may be a space of at least 5 μm between the section of grating closest to the output facet and the section of the output facet closest to the grating. The grating may be spaced from the output facet by a distance of 50 μm, and in some examples no more than 10 μm. That is, there may be a space of no more than 50 μm between the section of grating closest to the output facet and the section of the output facet closest to the grating.

The grating may be closer to the output facet than the reflective facet.

Etching the grating may be performed by a wet etch.

The grating may extend along at least 30% of a length of the active waveguide. The length of the active waveguide may be the one along which light is guided within the waveguide, i.e. along the guiding direction which may be a longitudinal direction. For example, for a distributed feedback laser where the active waveguide has a total length of around 400 μm the grating may extend for a distance of at least 120 μm.

The grating may extend along no more than 60% of a length of the active waveguide. The length of the active waveguide may be the one along which light is guided within the waveguide, i.e. along the guiding direction which may be a longitudinal direction. For example, for a distributed feedback laser where the active waveguide has a total length of around 400 μm the grating may extend for a distance of no more than 240 μm.

The output facet may be provided as a T-bar facet. The T-bar facet may be an angled T-bar facet. The angled T-bar facet may have an angle of at least 7° and no more than 10°. The angle may be measured relative to the upper bar of the T, that is, from a plane which is perpendicular to the guiding direction of the active waveguide.

The distributed feedback laser may include an antireflective coating disposed over at least the output facet. The antireflective coating may comprise one or more layers of silicon dioxide, and one or more layers of silicon nitride. In some embodiments the antireflective coating comprises a pair of silicon dioxide layers sandwiching a layer of silicon nitride.

The reflective facet may include a mirror. The reflective facet may be a highly reflective facet, in that it is more reflective than the grating. The reflective facet may be made of metal, such as Ti and Au, or at least partially lined with metal.

The grating may be a partial Bragg waveguide grating which may be referred to as a partially corrugated waveguide grating.

The active waveguide may be formed from a III-V semiconductor material.

In a second aspect, embodiments of the invention provide a distributed feedback laser, the distributed feedback laser comprising:
an active waveguide, which extends from a reflective facet to an output facet; and
a grating which extends part way along the active waveguide,
wherein the output facet is an etched facet.

Such a distributed feedback laser does not suffer the deficiencies identified above. Specifically, as the output facet is etched there is little or no phase change from the grating near the facet as it can be located more accurately than conventionally possible (for example to within an accuracy of ±100 nm). Accordingly, the SMSR is not affected in the same manner as in the prior art and the DFB laser has an improved yield.

The etched facet can be distinguished from a cleaved facet, for example, by examination under a microscope (e.g. optical microscope) or a scanning electron microscope. Traces of the etching process can be easily identified (e.g. facet vertical angle deviating from 90 degree or facet etch roughness) which would not be observed if the facet had been cleaved.

The distributed feedback laser may be located in a device coupon suitable for use in a micro-transfer printing process. The distributed feedback laser may be located on a wafer suitable for use in a flip-chip bonding process.

The grating may be closer to the output facet than the reflective facet.

The grating may extend along at least 30% of a length of the active waveguide. The length of the active waveguide may be the one along which light is guided within the waveguide, i.e. along the guiding direction which may be a longitudinal direction. For example, for a distributed feedback laser where the active waveguide has a total length of around 400 μm the grating may extend for a distance of at least 120 μm.

The grating may extend along no more than 60% of a length of the active waveguide. The length of the active waveguide may be the one along which light is guided within the waveguide, i.e. along the guiding direction which may be a longitudinal direction. For example, for a distributed feedback laser where the active waveguide has a total length of around 400 μm the grating may extend for a distance of no more than 240 μm.

The grating may be spaced from the output facet by a distance of at least 5 μm. That is, there may be a space of at least 5 μm between the section of grating closest to the output facet and the section of the output facet closest to the grating.

The grating may be spaced from the output facet by a distance of no more than 50 μm, in some examples it may be spaced by a distance of no more than 10 μm. That is, there may be a space of no more than 50 μm between the section of grating closest to the output facet and the section of the output facet closest to the grating.

The grating may be located above an active quantum well layer. The grating may be located underneath an active quantum well layer.

The output facet may be provided as a T-bar facet. The T-bar facet may be an angled T-bar facet. The angled T-bar facet may have an angle of at least 7° and no more than 10°. The angle may be measured relative to the upper bar of the T, that is, from a plane which is perpendicular to the guiding direction of the active waveguide.

The distributed feedback laser may include an antireflective coating disposed over at least the output facet. The antireflective coating may comprise one or more layers of silicon dioxide, and one or more layers of silicon nitride. In some embodiments the antireflective coating comprises a pair of silicon dioxide layers sandwiching a layer of silicon nitride. The antireflective coating reduces back reflections from the DFB laser, and reduces coupling losses as well.

The reflective facet may include a mirror. The reflective facet may be a highly reflective facet, in that it is more reflective than the grating. The reflective facet may be made of metal, such as Ti and Au or at least partially lined with metal.

The grating may be a partial waveguide Bragg grating, which may be referred to as a partially corrugated waveguide grating.

The active waveguide may be formed from a III-V semiconductor material.

In a third aspect, embodiments of the present invention provide an optoelectronic device comprising:
a distributed feedback laser, the distributed feedback laser comprising:
   an active waveguide, which extends from a reflective facet of the laser to an output facet of the laser, wherein the output facet is an etched facet; and
   a grating which extends part away along the active waveguide;
the optoelectronic device further comprising:
an output waveguide, butt coupled to the active waveguide.

The distributed feedback laser according to the third aspect may have any one, or any combination insofar as they are compatible, of the optional features of the distributed feedback laser of the second aspect.

The output waveguide may be formed of a different material to the active waveguide. The distributed feedback laser may be located within a cavity, the cavity may be located in a silicon device layer. The output waveguide may be located in a silicon device layer, which may be the same as the one in which the cavity is located. The optoelectronic device may comprise a silicon-on-insulator (SOI) wafer, and the silicon device layer may be the silicon-on-insulator layer. The distributed feedback laser may be bonded to the silicon device layer, e.g. a bed of the cavity. The distributed feedback laser may be bonded to an insulator layer of the SOI wafer, or the distributed feedback laser may be bonded to a substrate of the SOI wafer.

The active waveguide may be formed from a III-V semiconductor material.

The optoelectronic device may further comprise a mode converter, coupled to the output waveguide, and configured to convert light received from the output waveguide from a first optical mode to a second optical mode. The first optical mode is different to the second optical mode. The first optical mode may be smaller, that is have a smaller spot size, that the second optical mode. The mode converter may be provided coupled a further waveguide, and the mode converter may be provided as a transition region between the output waveguide and the further waveguide.

The output waveguide may have a T-bar facet coupled to the active waveguide. The T-bar facet of the output waveguide may be an angled T-bar facet. The angled T-bar facet of the output waveguide may have an angle of at least 7° and no more than 10°. The angle may be measured relative to the upper bar of the T, that is, from a plane which is perpendicular to the guiding direction of the active waveguide.

In a fourth aspect, embodiments of the present invention provide a method of fabricating an optoelectronic device via micro-transfer printing, using a device coupon containing the distributed feedback laser of the second aspect, the method comprising:
adhering the device coupon to a stamp; and
depositing the device coupon onto a platform wafer.

The platform wafer may be a SOI wafer of the type discussed above with reference to the third aspect.

In a fifth aspect, embodiments of the present invention provide an optoelectronic device fabricated using the method of the fourth aspect.

In a sixth aspect, embodiments of the present invention provide a method of fabricating an optoelectronic device via flip-chip bonding, using a device coupon containing the distributed feedback laser of the second aspect, the method comprising:
adhering the device coupon to a stamp; and
depositing the device coupon onto a platform wafer.

In a seventh aspect, embodiments of the present invention provide a distributed feedback laser, the distributed feedback laser comprising:
an active waveguide, which extends from a reflective facet to an output facet; and
a grating which extends part way along the active waveguide.

The distributed feedback laser of the seventh aspect may have any one, or any combination insofar as they are compatible, of the optional features of the distributed feedback laser of the second aspect.

In an eighth aspect, embodiments of the present invention provide an optoelectronic device comprising:
a distributed feedback laser, the distributed feedback laser comprising:
   an active waveguide, which extends from a reflective facet of the laser to an output facet of the laser; and
   a grating which extends part away along the active waveguide;
the optoelectronic device further comprising:
an output waveguide, butt coupled to the active waveguide.

The optoelectronic device of the eighth aspect may have anyone, or any combination insofar as they are compatible, of the optional features of the optoelectronic device of the third aspect. The distributed feedback laser according to the eighth aspect may have any one, or any combination insofar as they are compatible, of the optional features of the distributed feedback laser of the second aspect.

Further aspects of the present invention provide: a computer program comprising code which, when run on a computer, causes the computer to perform the method of the first and fourth aspects; a computer readable medium storing a computer program comprising code which, when run on a computer, causes the computer to perform the method of the first and fourth aspects; and a computer system programmed to perform the method of the first and fourth aspects.

### BRIEF DESCRIPTION OF THE DRAWINGS

Embodiments of the invention will now be described by way of example with reference to the accompanying drawings in which:

FIG. 1 shows a top-down schematic view of an optoelectronic device;

FIG. 2 shows a cross-sectional view of the device of FIG. 1 along the line A-A′;

FIG. 3A shows a cross-sectional view of the device of FIG. 1 along the line B-B′;

FIG. 3B shows a cross-sectional view of the device of FIG. 1 along the line C-C′;

FIG. 3C shows a cross-sectional view of the device of FIG. 1 along the line D-D′;

FIG. 3D shows a cross-sectional view of the device of FIG. 1 along the line E-E′;

FIG. 4 is a partial cross-sectional view showing in detail the antireflective coating structure of FIG. 1;

FIGS. 5A and 5B show schematic views of the grating; and

FIG. 6 shows a cross-sectional view of a variant of the device of FIG. 1 along the line A-A′.

### DETAILED DESCRIPTION AND FURTHER OPTIONAL FEATURES

Aspects and embodiments of the present invention will now be discussed with reference to the accompanying figures. Further aspects and embodiments will be apparent to those skilled in the art.

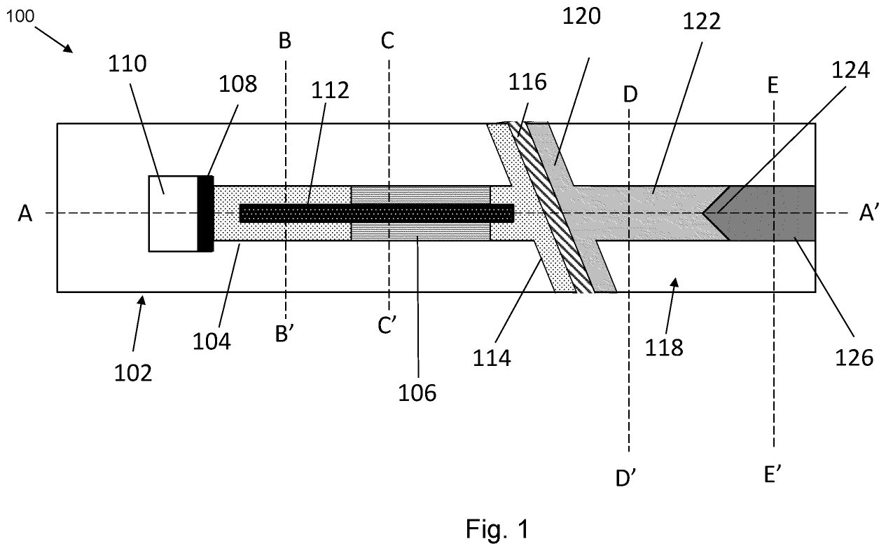

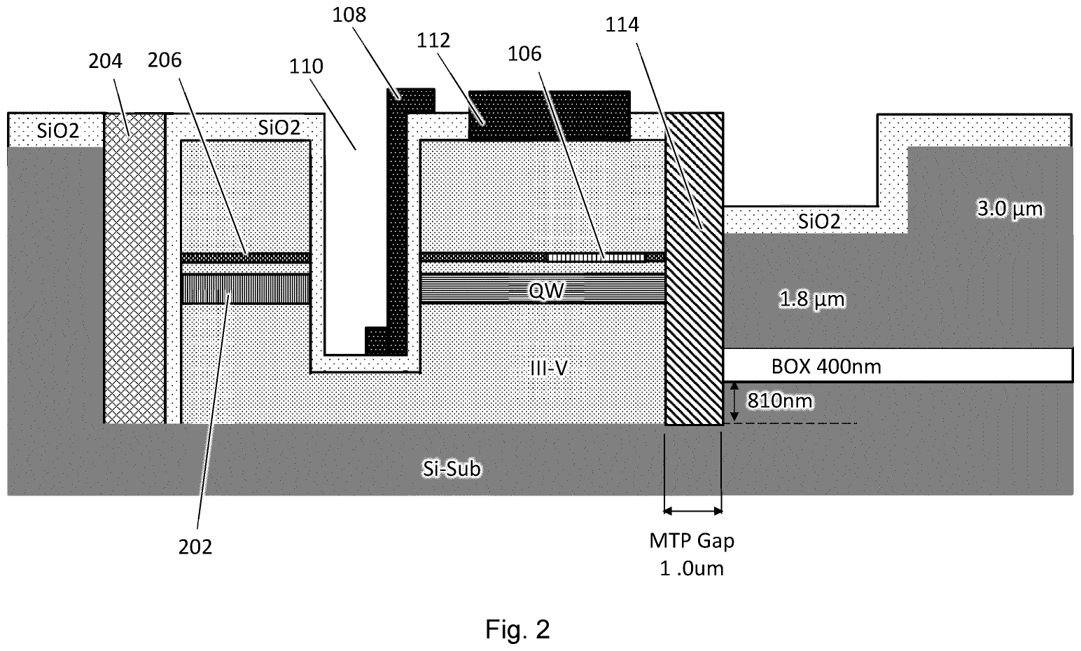

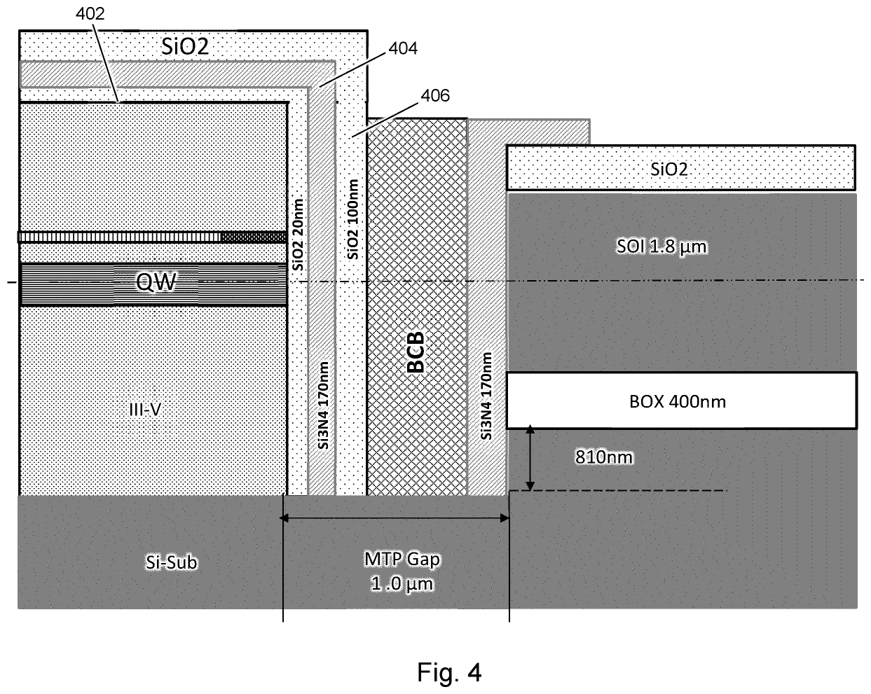

FIG. 1 shows a top-down schematic view of an optoelectronic device 100. The device comprises a device coupon 102, which has been positioned with a cavity of a silicon-on-insulator platform/wafer 118. As is shown in the cross-sectional view of FIG. 2, the device coupon in this example is bonded to a substrate of the wafer 118. The device coupon includes a distributed feedback laser which is formed of: an active waveguide 104, a grating 106, a highly reflective facet 108 and an output T-bar facet 114. The output T-bar facet of the distributed feedback laser is butt coupled to a corresponding T-bar facet 120 of an output waveguide 120 which is provided in the silicon device layer of the SOI wafer 118 forming the bulk of the optoelectronic device (which may also be referred to as the platform wafer). Between the T-bar facets is an antireflective coating 116, the structure of which is shown in detail in FIG. 4. An electrode 112 is connected to the upper surface of the active waveguide 104 (the electrode being a P or N electrode), and another electrode (not shown here) to connected to the laser diode's other side (the other electrode being the other of a N or P electrode), and these two electrodes can be driven so as to stimulate the emission of light by the laser.

The output waveguide 120 is connected to a mode converter 122, in this example a tapered region of the output waveguide and a further waveguide 126 to which the mode converter and/or output waveguide is coupled. In use, laser light is generated within the distributed feedback laser and leaks through T-bar facet 114 into the output waveguide 122. It is then mode converted by mode converter 124 and provided into the further waveguide 126 for further propagation.

In this example, the output waveguide 120 is around 1.8 μm tall (i.e. measured from the bottom cladding layer to the upper cladding layer/highest point of the SOI waveguide). The mode converter converts the optical mode within the 1.8 μm waveguide to one supported by the 3.0 μm tall further waveguide 126.

FIG. 2 shows a cross-sectional view of the device 100 of FIG. 1 along the line A-A′. The cross-sectional view shows in greater detail the space between grating 106 and the output facet 114 of the laser. Further, the void 110 in which the high reflection mirror can be seen. The structure of the active waveguide 104 is also shown in more detail. The active waveguide comprises a quantum well layer 202, located below a grating layer 206. The grating layer 206 is formed of a material which is different to the bulk III-V material making up the remaining active waveguide. For example, a material which has higher refractive index than the III-V material between QW and grating layer 206 and the III-V material above the grating layer 206 as well. In addition, the grating layer 206 also serves as etch stop layer in the waveguide ridge etching process to ensure no etch is performed below the grating layer of 206. In one example, the entire active waveguide, grating layer, and quantum well layer are all formed from multiple layers with different III-V materials. The grating layer may be InGaAsP, the quantum well layer may be AlInGaAs, the upper and lower III-V regions may be formed from InP (or mainly from InP). In a variant, the grating layer may be formed from InGaP, the quantum well layer from AlGaAs, and the upper and lower III-V regions from GaAs. The active waveguide is at least partially encapsulated by a silicon dioxide layer, which functions as an upper cladding and passivation layer. The device coupon is positioned so that the ARC coating 114 is butt coupled to the 1.8 μm silicon waveguide. In some embodiments there is no, or substantially no, gap between the device coupon and the 1.8 μm silicon waveguide. The silicon waveguide effectively provides a sidewall of the cavity against which the device coupon is positioned. The gaps between the device coupon and the other sidewalls are filled with a dielectric filler. In this example, a benzocyclobutene resin. In other embodiments, there is a gap between the device coupon and the 1.8 μm silicon waveguide. In such embodiments this gap is also filled with a dielectric filler.

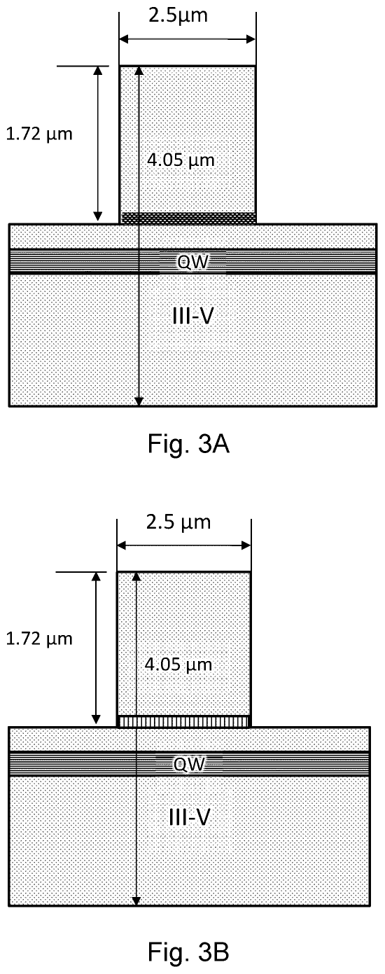

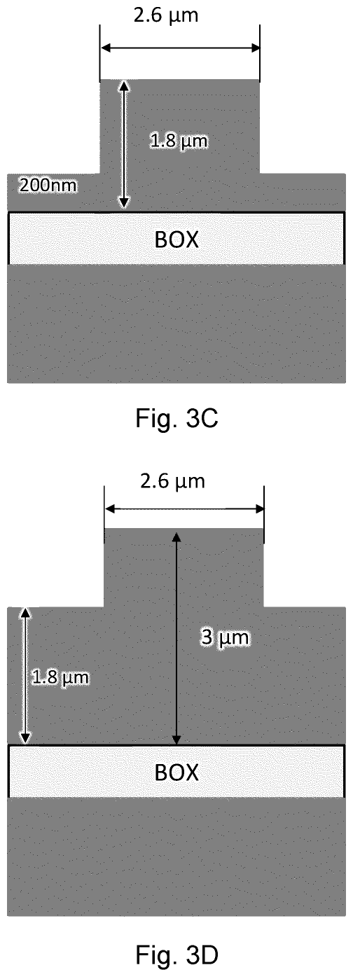

FIG. 3A shows a cross-sectional view of the device of FIG. 1 along the line B-B′. As can be seen, the active waveguide comprises a ridge and slab portion, the ridge extending from the slab away from the substrate of the device. The height of the ridge and slab is around 4.05 μm, whereas the height of the slab itself is around 1.72 μm. The ridge is around 2.5 μm wide, that is as measured in a direction perpendicular to the height and guiding direction but parallel to the substrate. In this cross-section, the grating layer 206 can be seen which does not at this position contain the grating structure. FIG. 3B shows a cross-sectional view of the device of FIG. 1 along the line C-C′ in which the grating can be seen.

FIG. 3C shows a cross-sectional view of the device of FIG. 1 along the line D-D′. This cross-section shows the dimensions of the output waveguide 122. The output waveguide comprises a ridge and slab in a similar manner to the active waveguide discussed above. The slab in this example has a height of around 200 nm as measured from an uppermost surface of the buried oxide layer (BOX) to an uppermost surface of the slab. The ridge has a height of around 1.8 μm as measured from an uppermost surface of the buried oxide layer to an uppermost layer of the ridge. The ridge has a width of around 2.6 μm, as measured in a direction perpendicular to the height and guiding direction of the output waveguide. FIG. 3D shows a cross-sectional view of the device of FIG. 1 along the line E-E′ and shows the dimensions of the further waveguide, which is coupled to the output waveguide via the mode converter. The further waveguide also has a slab and ridge, the slab having a height of around 1.8 μm and the ridge having a height of around 3 μm. The width of the ridge is around 2.6 μm.

FIG. 4 is a partial cross-sectional view showing in detail the antireflective coating structure of FIG. 1. The ARC coating on the device coupon comprises an inner silicon dioxide layer 402, which in this example is around 20 nm thick. Next, an intermediate silicon nitride (Si₃N₄) layer 404 is provided which in this example is around 170 nm thick. Finally, an outer silicon dioxide layer 406 is provided encapsulating the silicon nitride layer. The outer silicon dioxide layer is around 100 nm thick. In this example, the gap between the device coupon ARC and the ARC on the silicon waveguide (SOI 1.8 μm) is filled with a dielectric e.g. a benzocyclobutene resin. The silicon waveguide ARC includes a 170 nm thick silicon nitride (e.g. Si₃N₄) layer. The distance between the active waveguide and the silicon waveguide is around 1.0 μm and is referred to as the MTP gap. The cavity in which the device coupon is positioned has a bed which is around 810 nm lower than the lowermost surface of the buried oxide layer. That is, the cavity extends around 810 nm into the silicon substrate (Si-Sub) of the SOI wafer.

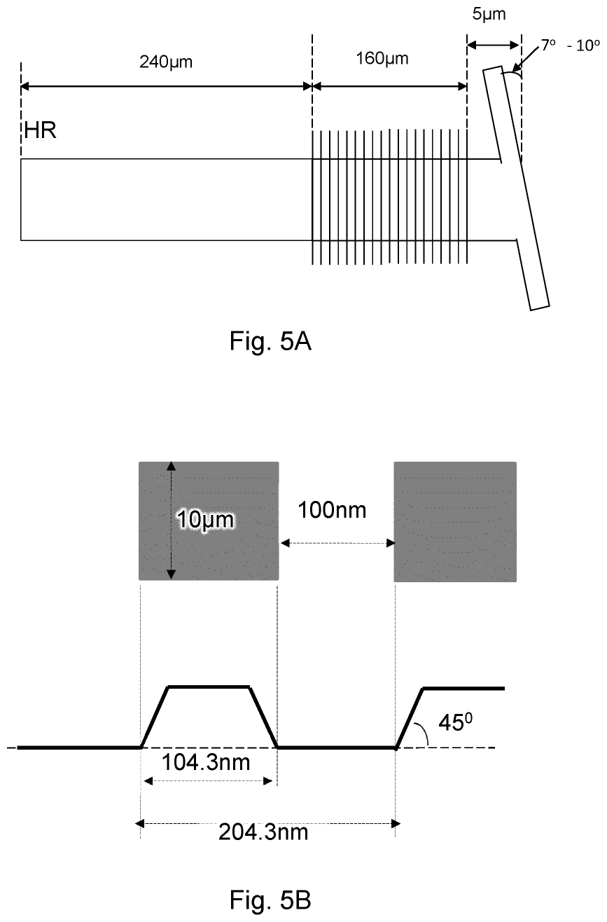

FIGS. 5A and 5B show schematic views of the grating 106. The grating in this example has a period of around 204.3 nm, and an etch opening (pitch, or distance between adjacent grating elements) of around 100 nm. The grating elements are around 104.3 nm long, and around 10 μm wide (i.e. across the active waveguide). The overall length of the grating in this example is around 160 μm, with a 5 μm spacing between the grating and the output facet and a 240 μm length of active waveguide which does not contain grating. The grating elements have a trapezoidal profile after etching. In this example the sidewalls have an angle of around 45° due to a wet etch being applied. The T-bar facet is angled at an angle between 7° and 10°.

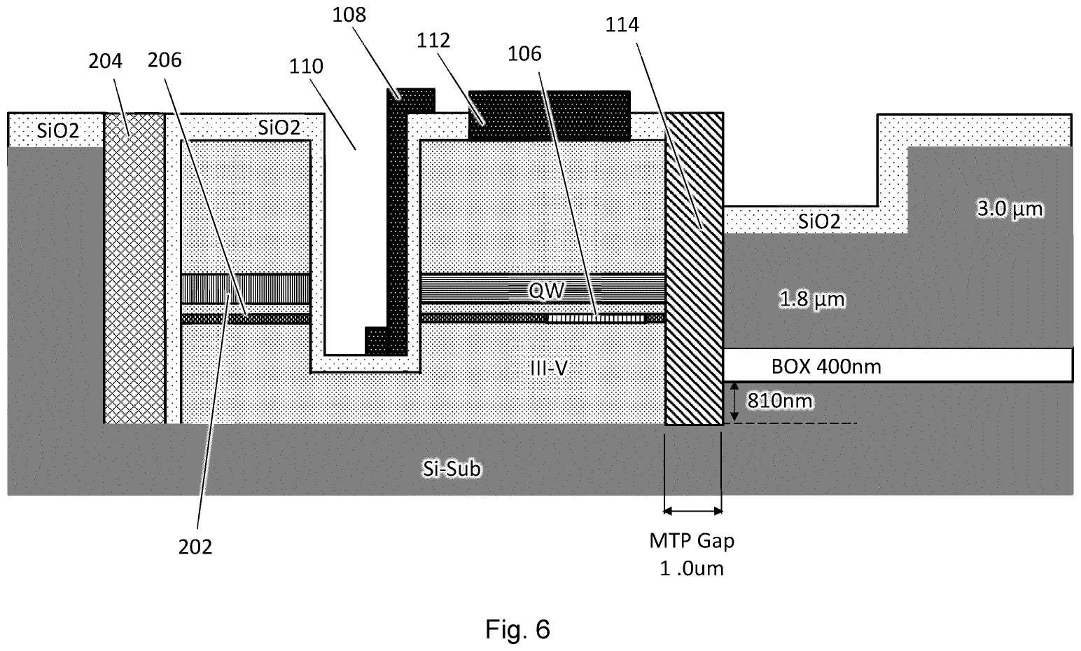

FIG. 6 shows a cross-sectional view of a variant of the device of FIG. 1 along the line A-A′. The variant differs from the examples shown previously in that the grating layer 206 and grating 106 in this example are located underneath the quantum well (QVV) active layers, i.e. between the QW active layers and the silicon substrate.

The features disclosed in the description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example+/−10%.

### LIST OF FEATURES

100 Optoelectronic device
102 Device coupon
104 Active waveguide
106 Grating
108 Reflective facet
110 Void for reflective facet
112 Electrode
114 Active waveguide T-bar facet
116 Antireflective coating
118 SOI platform
120 Output waveguide T-bar facet
122 Output waveguide
124 Mode converter
126 Further waveguide
202 QW layer
204 Dielectric fill
206 Grating layer
402 Inner silicon dioxide layer
404 Intermediate silicon nitride layer
406 Outer silicon dioxide layer

1. A method of preparing a distributed feedback laser, the distributed feedback laser comprising an active waveguide and a reflective facet;
the method comprising:
etching a grating into the active waveguide; and
etching an output facet into the active waveguide such that the grating is located between the reflective facet and the output facet.

2. The method of claim 1, wherein the grating is spaced from the output facet and extends part way along the active waveguide.

3. The method of claim 2, wherein the grating is spaced from the output facet by a distance of at least 0.5 μm and no more than 50 μm.

4. The method of claim 1, wherein the grating is closer to the output facet than the reflective facet.

5. The method of claim 1, wherein the grating extends along at least 30% of a length of the active waveguide.

6. The method of claim 1, wherein the grating extends along no more than 60% of a length of the active waveguide.

7. The method of claim 1, wherein the grating is located above an active quantum well layer.

8. The method of claim 1, wherein the grating is located underneath an active quantum well layer.

9. The method of claim 1, wherein the output facet is etched so as to provide an angled T-bar facet.

10. (canceled)

11. The method of claim 1, further including disposing an antireflective coating over at least the output facet.

12. The method of claim 11, wherein the antireflective coating comprises one or more layers of silicon dioxide, and one or more layers of silicon nitride.

13. The method of claim 1, further comprising providing a mirror on the reflective facet.

14. The method of claim 1, wherein the grating etched so as to provide a partial waveguide Bragg grating.

15. The method of claim 1, wherein the active waveguide is formed from a III-V semiconductor material.

16. A distributed feedback laser comprising:
an active waveguide, which extends from a reflective facet to an output facet; and
a grating which extends part way along the active waveguide;
wherein the output facet is an etched facet.

17. The distributed feedback laser of claim 16, wherein the grating is spaced from the output facet.

18. The distributed feedback laser of claim 17, wherein the grating is spaced from the output facet by a distance of at least 5 μm.

19. The distributed feedback laser of claim 17, wherein the grating is spaced from the output facet by a distance of no more than 50 μm.

20. (canceled)

21. The distributed feedback laser of claim 16, wherein the grating is closer to the output facet than the reflective facet.

22. (canceled)

23. (canceled)

24. An optoelectronic device, comprising:
a distributed feedback laser; and
an output waveguide,
the distributed feedback laser comprising:
an active waveguide, which extends from a reflective facet of the laser to an output facet of the laser, wherein the output facet is an etched facet; and
a grating which extends part way along the active waveguide, and
the output waveguide being butt coupled to the active waveguide.

25. (canceled)

26. (canceled)
